(19) United States
(12) Patent Application Publication
(10) Pub. No.: US 2024/0355986 A1
(43) Pub. Date: Oct. 24, 2024

(54) MICRO LIGHT-EMITTING DIODE PACKAGE STRUCTURE AND FORMING METHOD THEREOF

(71) Applicant: Lextar Electronics Corporation, Hsinchu City (TW)

(72) Inventors: Shiou-Yi KUO, Hsinchu City (TW); Guo-Yi SHIU, Hsinchu City (TW); Chin-Hung LO, Hsinchu City (TW); Chih-Hao LIN, Hsinchu City (TW); Cheng-Hsien LI, Hsinchu City (TW); Wei-Yuan MA, Hsinchu City (TW)

(21) Appl. No.: 18/633,418

(22) Filed: Apr. 11, 2024

(30) Foreign Application Priority Data
Apr. 19, 2023 (TW) 112114491
Feb. 26, 2024 (TW) 113106760

(51) Int. Cl. H01L 33/62; H01L 23/00; H01L 25/075

(52) U.S. Cl. CPC H01L 33/62; H01L 24/19; H01L 24/20; H01L 25/0753; H01L 2224/19; H01L 2224/211; H01L 2933/0066

(57) ABSTRACT

A micro light-emitting diode package structure and a forming method thereof are provided. The micro light-emitting diode package structure includes micro light-emitting diode dies, a light-transmitting layer, a first insulating layer, redistribution layers, and conductive elements. The micro light-emitting diode dies are disposed side by side and each includes an electrode surface, a light-emitting surface, and side surfaces. The electrode surface and the light-emitting surface are opposite to each other, and the side surfaces are between them. The light-transmitting layer covers the light-emitting surface and the side surfaces. The first insulating layer is under the micro light-emitting diode dies and in direct contact with the electrode surface. The redistribution layers are disposed under the first insulating layer and pass through the first insulating layer to electrically connect the electrode surface. The conductive elements are disposed under the redistribution layers and electrically connected to the redistribution layers.

### CROSS REFERENCE TO RELATED APPLICATIONS

This application claims priority of Taiwan Patent Application No. 112114491, filed on Apr. 19, 2023, and priority of Taiwan Patent Application No. 113106760, filed on Feb. 26, 2024, the entirety of which are incorporated by reference herein.

### BACKGROUND OF THE INVENTION

### Field of the Invention

The present disclosure relates to light-emitting diode and, in particular, to a micro light-emitting diode package structure and a forming method thereof.

### Description of the Related Art

With the rapid development of electronic devices, various elements of electronic devices are gradually being scaled down. Taking micro light-emitting diode package structures as an example, the reduction in the size of a light-emitting diode unit greatly increases the difficulty of the manufacturing process, leading to problems such as a decrease in yield. Therefore, although existing micro light-emitting diode package structures have largely met their intended purposes, they do not meet requirements in all respects. Therefore, some problems still need to be overcome regarding micro light-emitting diode package structures.

### BRIEF SUMMARY OF THE INVENTION

In some embodiments of the present disclosure, a micro light-emitting diode package structure is provided. The micro light-emitting diode package structure includes a plurality of micro light-emitting diode dies, a light-transmitting layer, a first insulating layer, a plurality of redistribution layers, and a plurality of conductive elements. The micro light-emitting diode dies are disposed side by side, and each one includes an electrode surface, a light-emitting surface, and a plurality of side surfaces. The electrode surface and the light-emitting surface are opposite to each other, and the side surfaces are between the electrode surface and the light-emitting surface. The light-transmitting layer covers the light-emitting surface and the side surfaces. The first insulating layer is under the micro light-emitting diode dies, and the electrode surface is in direct contact with the first insulating layer. The redistribution layers are disposed under the first insulating layer and pass through the first insulating layer to electrically connect the electrode surface. The conductive elements are disposed under the redistribution layers and electrically connected to the redistribution layers.

In some embodiments of the present disclosure, a forming method of a micro light-emitting diode package structure is provided. The forming method includes the following steps. A plurality of micro light-emitting diode dies are disposed side by side on a first substrate, wherein the micro light-emitting diode dies each includes an electrode surface, a light-emitting surface, and a plurality of side surfaces. The electrode surface and the light-emitting surface are opposite to each other, and the side surfaces are between the electrode surface and the light-emitting surface. A light-transmitting layer is disposed to cover the light-emitting surface and the side surfaces of the micro light-emitting diode dies. The first substrate is removed to expose the electrode surface of the micro light-emitting diode dies. A first insulating layer is disposed on the electrode surface of the micro light-emitting diode dies, wherein the first insulating layer is in direct contact with and covers the electrode surface of the micro light-emitting diode dies. A plurality of redistribution layers is disposed on the first insulating layer, wherein the redistribution layers pass through the first insulating layer and are electrically connected to the electrode surface of the micro light-emitting diode dies. A plurality of conductive elements is disposed on the redistribution layers, wherein the conductive elements are electrically connected to the redistribution layers.

The micro light-emitting diode package structure and the forming method thereof of the present disclosure can be applied in a variety of electrical devices. In order to make the features and advantages of the present disclosure more comprehensible, various embodiments are specially cited below, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 3A are schematic cross-sectional views showing the micro light-emitting diode package structure at various stages in the forming method according to some embodiments of the present disclosure.

FIG. 3B is an enlarged schematic diagram showing the micro light-emitting diode dies according to some embodiments of the present disclosure.

FIGS. 3C and 3D are schematic diagrams showing the micro light-emitting diode dies in a stamp transfer process according to some embodiments of the present disclosure.

FIG. 3E is a schematic diagram showing the upper surfaces of blue LEDs and green LEDs with periodically arranged concave and convex textures.

FIGS. 4 to 8A are schematic cross-sectional views showing the micro light-emitting diode package structure at various stages in the forming method according to some embodiments of the present disclosure.

FIG. 8B is a schematic diagram showing the electrodes and the solder paste connected together through the bonding process.

FIG. 8C is a schematic diagram showing the electrodes and redistribution layers connected together by an electroplating process, a sputtering process, or an electron gun evaporation process.

FIGS. 9 to 15 are schematic cross-sectional views showing the micro light-emitting diode package structure at various stages in the forming method according to some embodiments of the present disclosure.

FIG. 16 is a top view showing the micro light-emitting diode package structure according to some embodiments of the present disclosure.

FIGS. 17 to 21 are schematic cross-sectional views showing the micro light-emitting diode package structure at various stages in the forming method according to other embodiments of the present disclosure.

FIG. 22 is a top view showing the micro light-emitting diode package structure according to other embodiments of the present disclosure.

FIGS. 23A to 23C are schematic cross-sectional views showing the micro light-emitting diode package structure according to further embodiments of the present disclosure.

FIGS. 24A to 24D are schematic cross-sectional views showing the micro light-emitting diode package structure according to further embodiments of the present disclosure.

FIGS. 25 to 38 are schematic cross-sectional views showing the micro light-emitting diode package structure at various stages in the forming method according to further embodiments of the present disclosure.

FIG. 39 is a top view showing the micro light-emitting diode package structure according to further embodiments of the present disclosure.

FIG. 40 is a schematic diagram showing the display module according to some embodiments of the present disclosure.

FIG. 41 is a schematic diagram showing the spliced display device according to some embodiments of the present disclosure.

### DETAILED DESCRIPTION OF THE INVENTION

The following disclosure provides many different embodiments or examples for implementing the various features of the provided micro light-emitting diode package structure and the forming method thereof. Specific examples of features and their configurations are described below to simplify the embodiments of the present disclosure, but certainly not to limit the present disclosure. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The directional terms mentioned herein, such as “up”, “down”, “left”, “right”, and similar terms refer to the directions of the drawings. Accordingly, the directional terms used is to illustrate, not to limit, the present disclosure.

In some embodiments of the present disclosure, terms about disposing and connecting, such as “disposing”, “connecting” and similar terms, unless otherwise specified, may refer to two features are in direct contact with each other, or may also refer to two features are not in direct contact with each other, wherein there is an additional connect feature between the two features. The terms about disposing and connecting may also include the case where both features are movable, or both features are fixed.

In addition, ordinal numbers such as “first”, “second”, and the like used in the specification and claims are configured to modify different features or to distinguish different embodiments or ranges, rather than to limit the number, the upper or lower limits of features, and are not intended to limit the order of manufacture or arrangement of features.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”

Unless otherwise defined, all terms (including technical and scientific terms) used herein have the same meaning as commonly understood by one of ordinary skill in the art. It should be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

Some variations of the embodiments are described below. In different figures and described embodiments, the same or similar reference numerals are configured to refer to the same or similar features. It should be understood that additional steps may be provided before, during, and after the method, and that some described steps may be replaced or deleted for another embodiment of the method.

In the prior art, micro light-emitting diode dies are generally covered with packaging materials to ensure that the micro light-emitting diode dies are not contaminated by foreign impurities. In addition, packaging materials may also be used to electrically isolate multiple micro light-emitting diode dies from each other to ensure electrical stability. However, with the scaling down of the micro light-emitting diode dies, it is difficult for packaging materials to properly cover the micro light-emitting diode dies. Especially in order to scale down the dies, the original substrate of the micro light-emitting diode may be removed, which greatly reduces the thickness of the dies. Therefore, the traditional packaging technology of many process methods, such as picking up and bonding the die (ejector lifting/nozzle suction/fixing by pressuring), has become unfeasible for micro light-emitting diodes. Moreover, unintended pores are easily generated between the micro light-emitting diode die and the packaging material. These pores lead to unnecessary optical scattering and parasitic capacitance and reduce the heat dissipation effect. In addition, unexpected stress may also be generated in the packaging material, which may tear the micro light-emitting diode dies during manufacturing or use, to cause unexpected losses. Therefore, the present disclosure provides a micro light-emitting diode package structure and a forming method thereof to improve at least the above-mentioned problems of the prior art.

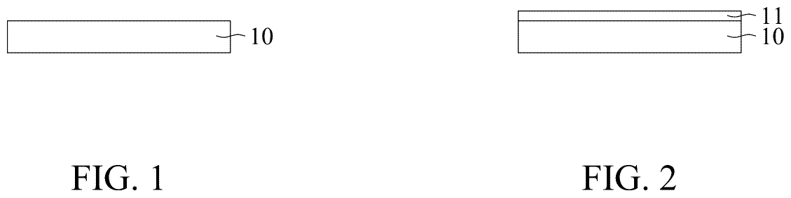

FIGS. 1 to 3A, FIGS. 4 to 8A, and FIGS. 9 to 15 are schematic cross-section views showing the micro light-emitting diode package structure at various stages in the forming method according to some embodiments of the present disclosure. As shown in FIG. 1, a first substrate 10 is provided. In some embodiments, the first substrate 10 may be or may include: Group IV elements or Group IV compounds, such as silicon (Si), diamond (C), and silicon carbide (SiC); Group III-V compounds, such as Gallium nitride (GaN), aluminum gallium nitride (AlGaN), aluminum nitride (AlN), gallium phosphide (GaP), gallium arsenide (GaAs), and aluminum gallium arsenide (AlGaAs); other suitable materials; or a combination thereof, but the present disclosure is not limited thereto. In some embodiments, the first substrate 10 may be or include a flexible substrate, a soft substrate, a rigid substrate, or a combination thereof, but the present disclosure is not limited thereto. In some embodiments, the first substrate 10 may be or may include glass, quartz, sapphire, ceramics, other suitable materials, or a combination thereof, but the present disclosure is not limited thereto. In some embodiments, the first substrate 10 may be or may include polyimide (PI), polycarbonate (PC), polyethylene terephthalate (PET), polypropylene (PP), other suitable materials, or a combination thereof, but the present disclosure is not limited thereto. For example, the first substrate 10 may be a sapphire substrate. In some embodiments, the first substrate 10 may be or may include a light-transmitting substrate, a semi-light-transmitting substrate, or an opaque substrate, but the present disclosure is not limited thereto.

As shown in FIG. 2, in some embodiments, a first debond layer 11 is disposed on the first substrate 10. In some embodiments, the first debond layer 11 may be or may include thermal release glue, UV release glue, other suitable materials, or a combination thereof, but the present disclosure is not limited thereto. It should be noted that although FIG. 2 illustrates an embodiment in which the first debond layer 11 completely covers the upper surface of the first substrate 10, the present disclosure is not limited thereto. In other embodiments, the first debond layer 11 may partially cover the upper surface of the first substrate 10. For example, the first debond layer 11 may partially cover the upper surface of the first substrate 10, corresponding to the position of a micro light-emitting diode die that will be disposed later.

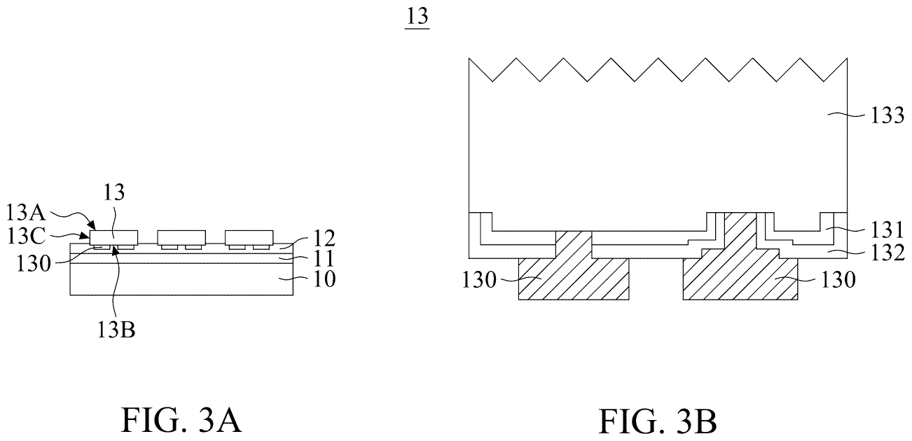

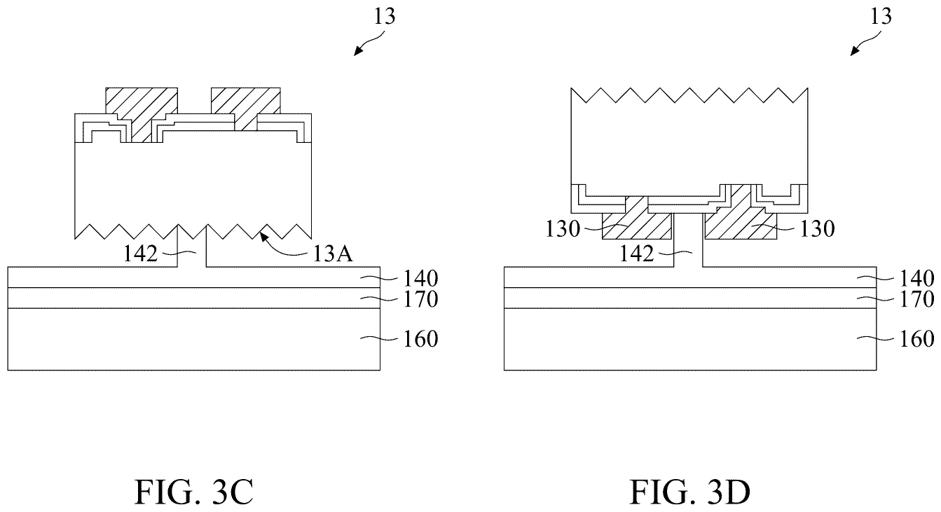

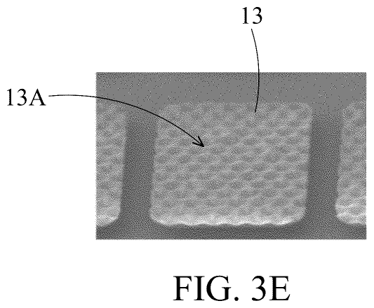

As shown in FIG. 3A, in some embodiments, the plurality of micro light-emitting diode dies 13 are disposed side by side on the first debond layer 11 on the first substrate 10. In some embodiments, the micro light-emitting diode die 13 may be or may include micro light-emitting diode dies 13 of the flip-chip type. For example, the micro light-emitting diode dies 13 may first be disposed on an adhesive layer (not shown) of a temporary substrate (not shown), and then the adhesive layer and the temporary substrate thereon are removed through a laser transfer process or the like, thereby transferring the micro light-emitting diode dies 13 to the first debond layer 11. However, the present disclosure is not limited thereto. Alternatively, the micro light-emitting diode dies 13 may also be transferred to the first debond layer 11 through a pick-up process.

FIG. 3B is an enlarged schematic diagram showing the micro light-emitting diode dies according to some embodiments of the present disclosure. As shown in FIG. 3B, in some embodiments, the micro light-emitting diode dies 13 of the flip-chip type may include two reflective layers, such as a first reflective layer 131 and a second reflective layer 132. The first reflective layer 131 is disposed on the micro light-emitting diode die (e.g., a semiconductor stack 133), wherein the first reflective layer 131 may reflect the emitted light band from the light-emitting diode die (e.g., the semiconductor stack 133), thereby increasing the external quantum efficiency (EQE) of the light-emitting diode and increasing the luminous efficiency of the light-emitting diode. The second reflective layer 132 is disposed on the first reflective layer 131. The second reflective layer 132 may reflect the laser, wherein the wavelength of the laser is less than 420 nm. The first reflective layer 131 is closer to the active layer (e.g., located in the semiconductor stack 133) of the micro light-emitting diode die 13 than the second reflective layer 132. Therefore, during the laser transfer process, the second reflective layer 132 is used to reflect the laser to prevent the laser from damaging the micro light-emitting diode die 13. In some embodiments, the micro light-emitting diode die 13 of the flip-chip type only includes the first reflective layer 131 for reflecting the emitted light band from the light-emitting diode die (e.g., the semiconductor stack 133), without including the second reflective layer 132 used to reflect the laser band.

FIGS. 3C and 3D are schematic diagrams showing micro light-emitting diode dies in the stamp transfer process according to some embodiments of the present disclosure. As shown in the figures, in some embodiments, the micro light-emitting diode dies 13 may be transferred to the first debond layer 11 by stamp transfer. The substrate used to transfer the micro light-emitting diode dies 13 includes a carrier substrate 160, an adhesive layer 170, and a sacrificial layer 140. The adhesive layer 170 is disposed on the carrier substrate 160, and the sacrificial layer 140 is disposed above the adhesive layer 170. In some embodiments, the sacrificial layer 140 may be etched to form a support frame 142 that supports the micro light-emitting diode die 13. When the micro light-emitting diode die 13 is transferred to the first debond layer 11 by stamp transfer, the micro light-emitting diode die 13 includes a support fracture part obtained by breaking the support frame 142. As shown in FIG. 3C, in some embodiments, the support fracture part is located on the light-emitting surface 13A of the micro light-emitting diode die 13. As shown in FIG. 3D, in some embodiments, the support fracture part is between the two electrodes 130 of the micro light-emitting diode die 13. However, the present disclosure is not limited thereto. The support frame 142 may be connected at any position of the micro light-emitting diode die 13, thereby leaving support fracture parts at various positions after breakage. For example, in some embodiments, the support fracture part is located on the side surface of the micro light-emitting diode die 13. In some embodiments, the support fracture part is located at a diagonal position on the side surface of the micro light-emitting diode die 13. In some embodiments, the micro light-emitting diode die 13 may include a plurality of support fracture parts.

As shown in FIG. 3A, in some embodiments, each of the micro light-emitting diode dies 13 has a light-emitting surface 13A, an electrode surface 13B, and a plurality of side surfaces 13C. The electrode surface 13B and the light-emitting surface 13A are opposite to each other, and the side surfaces 13C are between the electrode surface 13B and the light-emitting surface 13A. It should be noted that the electrode surface 13B herein refers to the surface of the micro light-emitting diode die 13 used to dispose the electrode 130 rather than the surface of the electrode 130. In some embodiments, the electrode surface 13B of the micro light-emitting diode die 13 is configured to electrically connect to other electronic elements through the electrode 130, and the light-emitting surface 13A is configured to generate a light source. In these embodiments, the electrode surface 13B of the micro light-emitting diode die 13 faces the first substrate 10, and the light-emitting surface 13A faces away from the first substrate 10.

In some embodiments, the micro light-emitting diode die 13 may be a red LED, a blue LED, or a green LED. In some embodiments, the light-emitting surfaces 13A of the red LED, blue LED, and green LED have roughened structures. In some embodiments, the light-emitting surface 13A of the blue LED or green LED of the micro light-emitting diode dies 13 has a uniform roughened structure. Referring to FIG. 3E, FIG. 3E shows the upper surface (the light-emitting surface 13A) of the blue LED and the green LED having periodically arranged concave and convex textures according to some embodiments of the present disclosure. For example, the blue LED and green LED themselves do not have an epitaxial substrate such as a patterned sapphire substrate (PSS) (e.g., the micro light-emitting diode die 13 includes the semiconductor stack 133 but does not include a patterned sapphire substrate), and the light-emitting surface 13A thereof has periodically arranged concave and convex textures generated after laser peeling off the patterned sapphire substrate. Specifically, the aforementioned concave and convex textures may be used to enhance light extraction and adjust the view angle of the micro light-emitting diode dies 13. In some embodiments, the light-emitting surface 13A of the red LED of the micro light-emitting diode dies 13 has an uneven roughened structure (e.g., uneven texture). In some embodiments, the light-emitting surface 13A may be performed chemical etched to produce the uneven roughened structure on the light-emitting surface 13A of the red LED of the micro light-emitting diode die 13.

It should be noted that although FIG. 3A and subsequent figures show the micro light-emitting diode dies 13 with equal thickness, the present disclosure is not limited thereto. In some embodiments, the micro light-emitting diode dies 13 may have different thicknesses. For example, any two of the red LED, the blue LED, and the green LED of the micro light-emitting diode dies 13 may have different thicknesses. For example, the blue LED and the green LED may have the same thickness, the blue LED and the red LED may have different thicknesses, and the green LED and the red LED may have different thicknesses. In this case, the light-emitting surfaces 13A of these micro light-emitting diode dies 13 with different thicknesses may be coplanar with each other through the redistribution layer provided later so as to maintain an excellent display effect.

Referring to FIG. 3A, in some embodiments, an adhesive layer 12 may be further disposed between the micro light-emitting diode dies 13 and the first debond layer 11. For example, the adhesive layer 12 may be disposed on the micro light-emitting diode dies 13 first, and the micro light-emitting diode dies 13 may be transferred to the first debond layer 11 along with the adhesive layer 12. Alternatively, the adhesive layer 12 may be disposed on the first debond layer 11 first, and the micro light-emitting diode dies 13 may be attached to the adhesive layer 12. In some embodiments, the adhesive layer 12 may be or may include polyimide (PI), polybenzoxazole (PBO), epoxy, other suitable materials, or a combination thereof, but the present disclosure is not limited thereto.

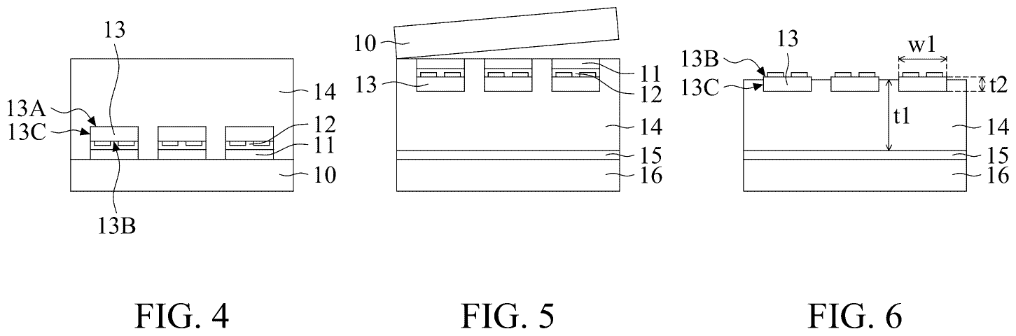

As shown in FIG. 4, in some embodiments, the adhesive layer 12 and the first debond layer 11 that are not covered by the micro light-emitting diode dies 13 are first removed. For example, heating, laser, UV light, etc. may be used to remove the adhesive layer 12 and the first debond layer 11 according to the materials of the adhesive layer 12 and/or the first debond layer 11, but the present disclosure is not limited thereto. In other embodiments, physical methods may also be used to remove the adhesive layer 12 and the first debond layer 11 in combination or separately. Following the above process, a light-transmitting layer 14 is disposed to cover the light-emitting surface 13A and the side surfaces 13C of the micro light-emitting diode die 13. For example, the light-transmitting layer 14 may be blanketly formed on the micro light-emitting diode dies 13 by compression molding, lamination, transfer molding, other suitable methods, or a combination thereof, to cover the light-emitting surface 13A and the side surfaces 13C of the micro light-emitting diode die 13, the side surface of the adhesive layer 12, the side surface of the first debond layer 11, and the first substrate 10 exposed from two micro light-emitting diode dies 13.

In some embodiments, the light-transmitting layer 14 may be or may include epoxy, silicone, polyurethane, other suitable materials, or a combination thereof, but the present disclosure is not limited thereto. In some embodiments, the Shore D hardness of the light-transmitting layer 14 may be less than or equal to 90. For example, the Shore hardness D of the light-transmitting layer 14 may be 90, 80, 70, 60, 50, 40, 30, or any range of the above values. When the Shore hardness D of the light-transmitting layer 14 is greater than 90, the chip may be cracked due to excessive stress during the curing process of the light-transmitting layer 14.

In some embodiments, the light emitted by the micro light-emitting diode die 13 transmits outward from the light-emitting surface 13A and the light-transmitting layer 14 in sequence. Therefore, the light transmittance of the light-transmitting layer 14 (e.g., the light transmittance of the visible light range) may be greater than or equal to 80% to provide a better display effect, but the present disclosure is not limited thereto. For example, the light transmittance of the light-transmitting layer 14 may be 80%, 85%, 90%, 95%, 100%, or any range of the above values.

As shown in FIG. 5, in some embodiments, the second substrate 16 is first bonded to the light-transmitting layer 14, and then the first substrate 10 is turned over. For example, the second debond layer 15 may be disposed on the second substrate 16 first, and then the second substrate 16 may be bonded to the light-transmitting layer 14 through the second debond layer 15. Alternatively, the second debond layer 15 may also be disposed on the light-transmitting layer 14 first, and then the second substrate 16 is bonded to the second debond layer 15.

In some embodiments, the second substrate 16 may be or may include: Group IV elements or Group IV compounds, such as silicon, diamond, and silicon carbide; Group III-V compounds, such as gallium nitride (GaN), nitride aluminum gallium (AlGaN), aluminum nitride (AlN), gallium phosphide (GaP), gallium arsenide (GaAs), and aluminum gallium arsenide (AlGaAs); other suitable materials; or a combination thereof, but the present disclosure is not limited thereto. In some embodiments, the second substrate 16 may be or include a flexible substrate, a soft substrate, a rigid substrate, or a combination thereof, but the present disclosure is not limited thereto. In some embodiments, the second substrate 16 may be or may include glass, quartz, sapphire, ceramic, other suitable materials, or a combination thereof, but the present disclosure is not limited thereto. In some embodiments, the second substrate 16 may be or may include polyimide (PI), polycarbonate (PC), polyethylene terephthalate (PET), polypropylene (PP), other suitable materials, or a combination thereof, but the present disclosure is not limited thereto. For example, the second substrate 16 may be a sapphire substrate. In some embodiments, the second substrate 16 may be or may include a light-transmitting substrate, a semi-light-transmitting substrate, or an opaque substrate, but the present disclosure is not limited thereto. In some embodiments, the material of the second substrate 16 may be similar to or the same as the material of the first substrate 10, but the present disclosure is not limited thereto.

In some embodiments, the second debond layer 15 may be or may include thermal release glue, light release glue, other suitable materials, or a combination thereof, but the present disclosure is not limited thereto. In some embodiments, the material of the second debond layer 15 may be similar to or the same as the material of the first debond layer 11, but the present disclosure is not limited thereto.

Following the above process, the first substrate 10 is removed. In some embodiments, the first substrate 10 may be removed through a laser lift-off process, other suitable processes, or a combination thereof, but the present disclosure is not limited thereto. For example, the first substrate 10 may be removed by removing the adhesive between the first substrate 10 and the micro light-emitting diode dies 13 (if present, and the adhesive is not shown). It should be noted that the above methods are only examples, and the present disclosure is not limited thereto. In some other embodiments, a portion of the first substrate 10 may also be directly removed by physical destruction to separate it from the micro light-emitting diode dies 13.

As shown in FIG. 6, in some embodiments, after removing the first substrate 10, the first debond layer 11, the adhesive layer 12, and a portion of the light-transmitting layer 14 are removed to expose the electrode surface 13B of the micro light-emitting diode dies 13 and a portion of the side surfaces 13C. In some embodiments, the above materials may be removed through an etching process, a grinding process, other suitable processes, or a combination thereof, but the present disclosure is not limited thereto.

In some embodiments, after removing a portion of the light-transmitting layer 14, the ratio between the thickness t1 of the remaining light-transmitting layer 14 and the thickness t2 of the micro light-emitting diode die 13 ranges from 1:1 to 30:1, but the present disclosure is not limited thereto. For example, the ratio between the thickness t1 of the light-transmitting layer 14 and the thickness t2 of the micro light-emitting diode die 13 may be 1:1, 3:1, 5:1, 7:1, 10:1, 15:1, 20:1, 25:1, any value or any value range between the above values. In some embodiments, the ratio between the thickness t1 of the light-transmitting layer 14 and the width w1 of the micro light-emitting diode die 13 is between 30:1 and 0.4:1, but the present disclosure is not limited thereto. For example, the ratio between the thickness t1 of the light-transmitting layer 14 and the width w1 of the micro light-emitting diode dies 13 may be 30:1, 20:1, 15:1, 10:1, 5:1, 2:1, 1:1, 0.4:1, any value or any value range between the above values. By establishing a specific relationship between the thickness of the light-transmitting layer 14 and the thickness/width of the micro light-emitting diode die 13, the display effect of the entire device may be effectively improved.

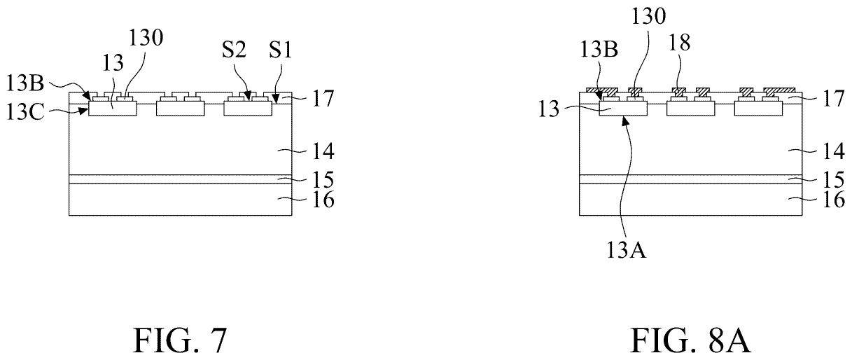

As shown in FIG. 7, in some embodiments, a first insulating layer 17 is disposed on the electrode surface 13B of the micro light-emitting diode die 13, wherein the first insulating layer 17 is in direct contact with the electrode surface 13B of the micro light-emitting diode die 13, and the electrodes 130 of the micro light-emitting diode die 13 are exposed. In some embodiments, the micro light-emitting diode die 13 has two electrodes 130, and the two electrodes 130 are spaced apart from each other. In this case, the first insulating layer 17 fills the gap between the two electrodes 130 to ensure that the electrode surface 13B of the micro light-emitting diode die 13 is completely covered by the first insulating layer 17 except for the electrode 130. In some embodiments, the first insulating layer 17 continuously surrounds the side surfaces of the micro light-emitting diode die 13. In some embodiments, the first insulating layer 17 continuously surrounds the side surfaces of the electrodes 130 of the micro light-emitting diode die 13.

In some embodiments, the first contact surface S1 is between the first insulating layer 17 and the light-transmitting layer 14, the second contact surface S2 is between the first insulating layer 17 and the electrode surface 13B of the micro light-emitting diode die 13, and the first contact surface S1 and the second contact surface S2 are not coplanar. Specifically, through the aforementioned removal process, the level of the remaining light-transmitting layer 14 is lower than the electrode surface 13B. Therefore, the level of the first contact surface S1 in FIG. 7 is lower than that of the second contact surface S2. The first insulating layer 17 further partially covers the side surfaces 13C of the micro light-emitting diode die 13. By partially covering the side surfaces 13C of the micro light-emitting diode die 13 with the first insulating layer 17, the contact area between the first insulating layer 17 and the micro light-emitting diode die 13 may be increased, thereby increasing the tightness between the two elements. In some embodiments, the first insulating layer 17 continuously surrounds a portion of the side surfaces 13C of the micro light-emitting diode die 13.

In some embodiments, the first insulating layer 17 may be or may include epoxy, polyimide (PI), polybenzoxazole (PBO), silicone, silicon dioxide, silicon nitride, or a combination thereof, but the present disclosure is not limited thereto. In some embodiments, the material of the first insulating layer 17 is different from the material of the light-transmitting layer 14. In other embodiments, the material of the first insulating layer 17 may be similar to the material of the light-transmitting layer 14, but at least some of their physical properties are different. For example, the hardness of the first insulating layer 17 may be different from the hardness of the light-transmitting layer 14. Alternatively, the light transmittance of the first insulating layer 17 may be different from the light transmittance of the light-transmitting layer 14.

In some embodiments, the Shore D hardness of the first insulating layer 17 may be greater than or equal to 40. For example, the Shore hardness D of the first insulating layer 17 may be 40, 50, 60, 70, 80, 90, 100, or any range of the above values. When the Shore hardness D of the first insulating layer 17 is less than the above value, the first insulating layer 17 may crack the chip due to inward extension of stress during subsequent processes.

In some embodiments, the light transmittance (e.g., the light transmittance of the visible light range) of the first insulating layer 17 may be less than or equal to 70%. For example, the light transmittance of the first insulating layer 17 may be 70%, 65%, 60%, 55%, 50%, 45%, 40%, 35%, or any range of the above values. In some embodiments, the light transmittance of the first insulating layer 17 may be less than the light transmittance of the light-transmitting layer 14. In some embodiments, the first insulating layer 17 may be made of or include a material with a light absorption rate greater than 90% to adjust the light transmittance of the first insulating layer 17. For example, black dispersed particles such as carbon black may be added to the first insulating layer 17 so that the light transmittance of the first insulating layer 17 is less than 10%. Therefore, the first insulating layer 17 appears black. By making the first insulating layer 17 appear black, the proportion of black in each micro light-emitting diode package structure may be increased in a top view, thereby improving the display effect of the entire device. For example, the contrast of a display device including the micro light-emitting diode package structure may be improved. In some embodiments, the high proportion of black in the micro light-emitting diode package structure may reach more than 80%.

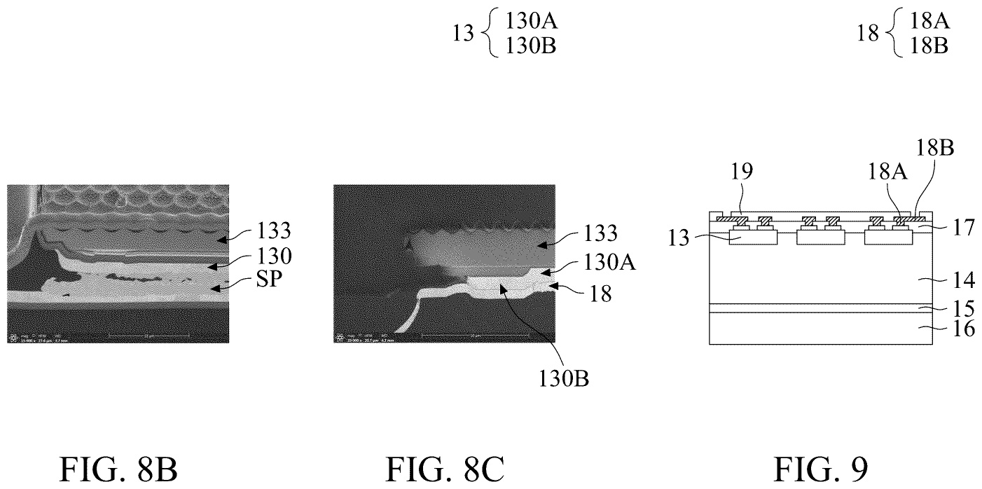

As shown in FIG. 8A, in some embodiments, a plurality of redistribution layers 18 is disposed on the first insulating layer 17, wherein the redistribution layers 18 pass through the first insulating layer 17 and are electrically connected to the electrode 130 on the electrode surface 13B of the micro light-emitting diode die 13.

In some embodiments, the redistribution layers 18 may be formed on the electrode 130 by a plating process such as electroplating, sputtering, or an electron gun evaporation process. In this case, the contact surface between the redistribution layer 18 and the electrodes 130 may have a clear demarcation and may be a flat surface. Referring to FIG. 8B, FIG. 8B is a schematic diagram showing the electrode 130 and the solder paste SP connected together through a bonding process. Specifically, compared with the rough interface that may be produced by the bonding process (e.g., as shown in FIG. 8B, the electrode 130 and the solder paste SP have a fuzzy interface). FIG. 8C is a schematic diagram showing the electrode and the redistribution layer connected together through an electroplating process, a sputtering process, or an electron gun evaporation process. The contact surface between the redistribution layer 18 and the electrodes 130 formed by the electroplating, the sputtering process, or the electron gun evaporation process may have a smooth interface (as the clear interface presented in FIG. 8C). In other words, the roughness of the contact surface between the redistribution layer 18 and the electrodes 130 is smaller than the roughness of the contact surface that may be produced by the bonding process. For example, the maximum roughness of the contact surface between the redistribution layer 18 and the electrodes 130 does not exceed 1 μm, but the present disclosure is not limited thereto. Because the contact surface between the redistribution layer 18 and the electrodes 130 has a clear boundary and may be a flat surface, the reliability of the micro light-emitting diode package structure 1 may be improved.

In some embodiments, the redistribution layer 18 is conformally formed on the surface of electrode 130. Therefore, the redistribution layer 18 conforms to the surface shape of the electrode 130. For example, as shown in FIG. 8C, the electrode 130 of the micro light-emitting diode die 13 may have the upper part 130A and the lower part 130B, and the upper part 130A and the lower part 130B have a step. In this case, the redistribution layer 18 is disposed on the electrode 130 along the upper portion 130A, the lower portion 130B, and the step therebetween and has a shape similar to the electrode 130.

As shown in FIG. 9, in some embodiments, the redistribution layer 18 may include a vertical connection portion 18A and a horizontal connection portion 18B, wherein the vertical connection portion 18A is configured to electrically connect the micro light-emitting diode die 13, and the horizontal connection portion 18B is configured to electrically connect other electronic elements, such as a conductive element 20 that will be described hereinafter. In some embodiments, when the total thickness of the semiconductor stacks of the micro light-emitting diode dies 13 are different from each other, the extension length (or thickness) of the vertical connection portion 18A of the redistribution layer 18 may be different from each other. In this way, the light-emitting surface 13A of each micro light-emitting diode die 13 may be substantially coplanar, and the horizontal connection portion 18B of the redistribution layer 18 corresponding to each micro light-emitting diode die 13 may be substantially coplanar.

In some embodiments, the redistribution layer 18 may be or may include a conductive material. For example, the conductive material may include metal, metal compounds, other suitable conductive materials, or a combination thereof, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or alloys thereof. For example, the metal compound may be tantalum nitride (TaN), titanium nitride (TiN), tungsten silicide (WSi₂), indium tin oxide (ITO), etc.

As shown in FIG. 9, in some embodiments, a second insulating layer 19 is disposed on the first insulating layer 17, wherein the second insulating layer 19 covers the redistribution layer 18. In other words, the redistribution layer 18 is buried in the second insulating layer 19. In some embodiments, the second insulating layer 19 may be or may include epoxy, polyimide, polyphenylene oxazole, silicone, silicon oxide, silicon nitride, or a combination thereof, but the present disclosure is not limited thereto. In some embodiments, the material of the second insulating layer 19 may be similar to or the same as the material of the first insulating layer 17, but the present disclosure is not limited thereto.

In some embodiments, the light transmittance (e.g., the light transmittance of the visible light range) of the second insulating layer 19 may be less than or equal to 70%. For example, the light transmittance of the second insulating layer 19 may be 70%, 65%, 60%, 55%, 50%, 45%, 40%, 35%, or any range of the above values. In some embodiments, the light transmittance of the second insulating layer 19 may be less than the light transmittance of the light-transmitting layer 14. In some embodiments, the second insulating layer 19 may be made of or include a material with a light absorption rate greater than 90% to adjust the light transmittance of the second insulating layer 19. For example, black dispersed particles such as carbon black may be added to the second insulating layer 19 so that the light transmittance of the second insulating layer 19 is less than 10%. Therefore, the second insulating layer 19 appears black. By making the second insulating layer 19 appear black, the proportion of black in each micro light-emitting diode package structure may be increased in a top view, thereby improving the display effect of the entire device.

In some embodiments, the light transmittance of the second insulating layer 19 is greater than the light transmittance of the first insulating layer 17. For example, the first insulating layer 17 may be made to appear opaque black, and the second insulating layer 19 may be made to appear transparent or translucent in any color. In this case, a high proportion of black in each micro light-emitting diode package structure may be maintained in a top view. In some embodiments, the high proportion of black is more than 80%; however, the present disclosure is not limited thereto. In some embodiments, the first insulating layer 17 may be made to appear opaque black, and the second insulating layer 19 may be made to appear translucent or opaque black so as to further improve the high proportion of black of each micro light-emitting diode package structure in a top view.

As shown in FIG. 10, the conductive elements 20 are disposed on the second insulating layer 19 and the redistribution layer 18, wherein the conductive elements 20 are electrically connected to the redistribution layer 18. In some embodiments, the conductive element 20 may be a bonding pad, but the present disclosure is not limited thereto. In some embodiments, the conductive element 20 may be or may include conductive material. For example, the conductive material may include metal, metal compounds, other suitable conductive materials, or a combination thereof, but the present disclosure is not limited thereto. For example, the metal may be tin, copper, gold, silver, nickel, indium, platinum, palladium, iridium, titanium, chromium, tungsten, aluminum, molybdenum, titanium, magnesium, zinc, germanium, or alloys thereof. For example, the metal compound may be tantalum nitride, titanium nitride, tungsten silicide, indium tin oxide, etc. In some embodiments, the material of the conductive element 20 may be similar to or the same as the material of the redistribution layer 18, but the present disclosure is not limited thereto.

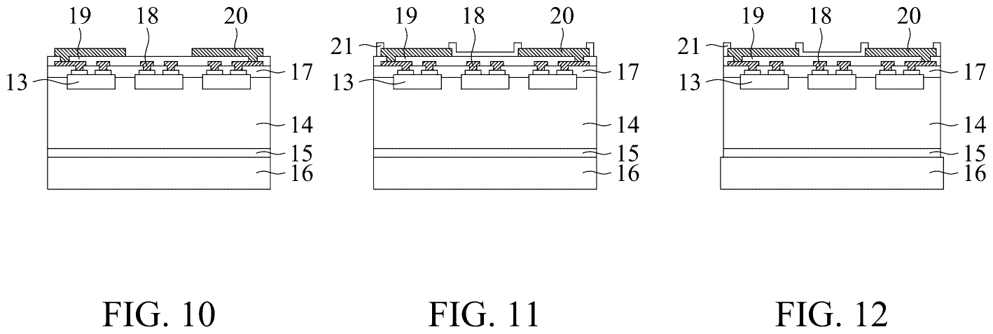

As shown in FIG. 11, in some embodiments, a hard mask layer 21 is disposed on the second insulating layer 19, wherein the hard mask layer 21 surrounds the conductive element 20. In some embodiments, the patterned hard mask layer 21 may be formed by a photolithography process, other suitable processes, or a combination thereof, but the present disclosure is not limited thereto. In some embodiments, the hard mask layer 21 includes silicon oxide, but the present disclosure is not limited thereto. In some embodiments, the hard mask layer 21 may expose a portion of the second insulating layer 19 so that the exposed second insulating layer 19 may be used as a cutting area for subsequent processes. In some embodiments, three micro light-emitting diode dies 13 may be defined as one group, and the second insulating layer 19 between the multiple groups of micro light-emitting diode dies 13 is exposed (that is, not covered by hard mask layer 21). It should be noted that the above quantities are only examples, and the present disclosure is not limited thereto.

As shown in FIG. 12, by using the hard mask layer 21 as a protective layer, the second insulating layer 19 and the first insulating layer 17, the light-transmitting layer 14, and the second debond layer 15 below the second insulating layer 19, which are between one group (e.g., the three shown in FIG. 12) of micro light-emitting diode dies 13 and another group (not shown) of the micro light-emitting diode dies 13, are cut until reaching the second substrate 16. For example, the plasma dicing may be used to perform the above steps, but the present disclosure is not limited thereto. In other embodiments, the cutting process for the two groups of micro light-emitting diode dies 13 may also be performed by using lasers, knives, other suitable methods or tools, or a combination thereof. In some embodiments, there may be multiple groups of micro light-emitting diode dies 13 on one second substrate 16, and the light-transmitting layer 14 covering one group of micro light-emitting diode dies 13, the first insulating layer 17, and the second insulating layer 19 are disconnected from the corresponding elements covering another group of micro light-emitting diode dies 13 after this cutting step.

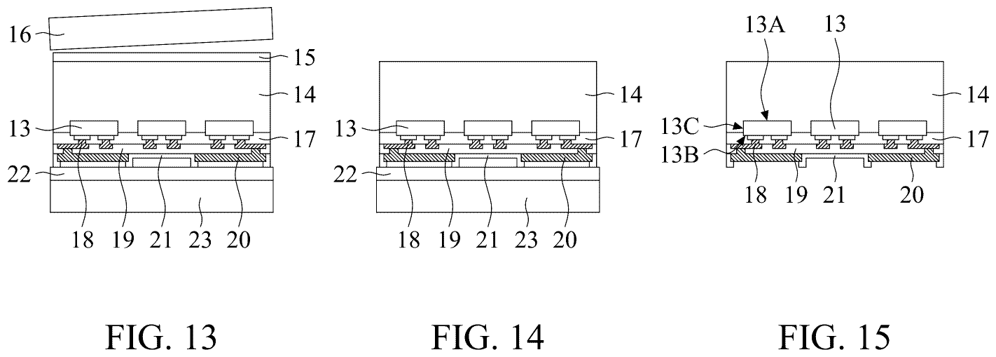

As shown in FIGS. 13 to 14, in some embodiments, a third substrate 23 is bonded to the conductive element 20 first, and the second substrate 16 is turned over. For example, the third debond layer 22 may be disposed on the third substrate 23 first, and then the third substrate 23 may be bonded to the conductive element 20 through the third debond layer 22. Alternatively, the third debond layer 22 may also be disposed on the conductive element 20 first, and then the third substrate 23 is bonded to the third debond layer 22.

In some embodiments, the third substrate 23 may be or may include: Group IV elements or Group IV compounds, such as silicon, diamond, and silicon carbide; Group III-V compounds, such as gallium nitride (GaN), nitride aluminum gallium (AlGaN), aluminum nitride (AlN), gallium phosphide (GaP), gallium arsenide (GaAs), and aluminum gallium arsenide (AlGaAs); other suitable materials; or a combination thereof, but the present disclosure is not limited thereto. In some embodiments, the third substrate 23 may be or include a flexible substrate, a soft substrate, a rigid substrate, or a combination thereof, but the present disclosure is not limited thereto. In some embodiments, the third substrate 23 may be or may include glass, quartz, sapphire, ceramics, other suitable materials, or a combination thereof, but the present disclosure is not limited thereto. In some embodiments, the third substrate 23 may be or may include polyimide (PI), polycarbonate (PC), polyethylene terephthalate (PET), polypropylene (PP), other suitable materials, or a combination thereof, but the present disclosure is not limited thereto. For example, the third substrate 23 may be a sapphire substrate. In some embodiments, the third substrate 23 may be or may include a light-transmitting substrate, a semi-light-transmitting substrate, or an opaque substrate, but the present disclosure is not limited thereto. In some embodiments, the material of the third substrate 23 may be similar to or the same as the material of the first substrate 10, but the present disclosure is not limited thereto. In some embodiments, the third debond layer 22 may be or may include thermal release glue, light release glue, other suitable materials, or a combination thereof, but the present disclosure is not limited thereto. In some embodiments, the material of the third debond layer 22 may be similar to or the same as the material of the first debond layer 11, but the present disclosure is not limited thereto.

Following the above process, the second substrate 16 is removed. For example, the second debond layer 15 may lose its adhesion by heating, UV light, laser, etc. according to the type of the second debond layer 15, so as to remove the second substrate 16 thereon. Then, the second debond layer 15 may be removed by physical means or chemical means. It should be noted that the second debond layer 15 and the second substrate 16 may also be removed simultaneously in the same step using a suitable process, and the present disclosure is not limited to the above method.

As shown in FIG. 15, in some embodiments, the third substrate 23 is removed. For example, the third debond layer 22 may lose its adhesion by heating, UV light, laser, etc. according to the type of the third debond layer 22, so as to remove the third substrate 23 thereon. Then, the third debond layer 22 may be removed by physical means or chemical means. It should be noted that the third debond layer 22 and the third substrate 23 may also be removed simultaneously in the same step using a suitable process, and the present disclosure is not limited to the above method.

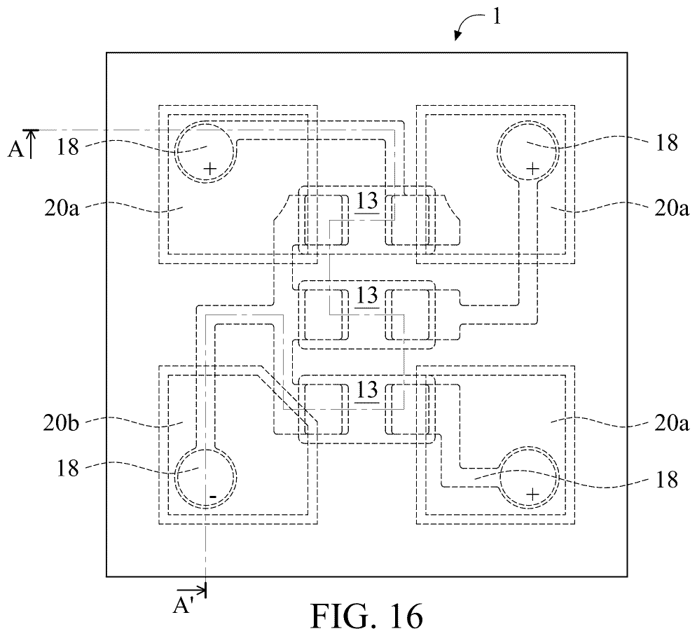

FIG. 16 is a top view showing the micro light-emitting diode package structure according to some embodiments of the present disclosure, and FIG. 15 is a cross-sectional view of line AA′ in FIG. 16. As shown in FIG. 16, after going through the above steps, the micro light-emitting diode package structure 1 is formed. In some embodiments, the conductive elements 20 may be the negative conductive element 20b or the positive conductive element 20a. Among them, the micro light-emitting diode package structure 1 has three micro light-emitting diode dies 13 disposed side by side, and the electrode 130 of each micro light-emitting diode die 13 is electrically connected to one common negative electrode. The other electrode 130 of each micro light-emitting diode die 13 is respectively connected to the conductive element 20a of the positive electrode. In some embodiments, the shapes of the conductive elements 20 may be the same in the top view. In some embodiments, the shapes of the conductive elements 20 may be different in the top view. In some embodiments, the common conductive element 20 is square in shape and has a triangular missing corner, and the other non-common conductive elements 20 are square in shape. In some embodiments, the triangular missing corner of the common conductive element 20 may be located at the upper left corner, upper right corner, lower left corner, or lower right corner of the square. In some embodiments, the shape of the common conductive element 20 is a square with two triangular missing corners. It should be noted that the structure shown in FIG. 16 is only an example, and the present disclosure is not limited thereto. In other embodiments, the micro light-emitting diode package structure 1 may have more than three or less than three micro light-emitting diode dies 13, and the multiple micro light-emitting diode dies 13 may be individually connected to different conductive elements 20. In some embodiments, the electrode connection type of the micro light-emitting diode dies 13 in the micro light-emitting diode package structure 1 may be different from the above. For example, one electrode 130 of each micro light-emitting diode die 13 is electrically connected to one common positive conductive element, and the other electrode 130 of each micro light-emitting diode die 13 is respectively connected to one negative conductive element (not shown).

Through the above steps, the micro light-emitting diode package structure 1 with a simple manufacturing process may be realized. On the other hand, by having the first insulating layer 17 cover the micro light-emitting diode die 13 over a large area and partially laterally, the stress control around the micro light-emitting diode dies 13 may also be ensured, and better insulation between the micro light-emitting diode dies 13 and other elements is achieved. Therefore, the micro light-emitting diode package structure 1 with high yield is realized. In addition, compared with electrical testing on a single micro light-emitting diode die 13, electrical testing on the micro light-emitting diode package structure 1 as a unit may greatly reduce the difficulty of detection, thereby reducing the cost of testing. This is due to the transfer of the detection contacts that are composed of six electrodes 130 in a small area to four conductive elements 20 in a large area.

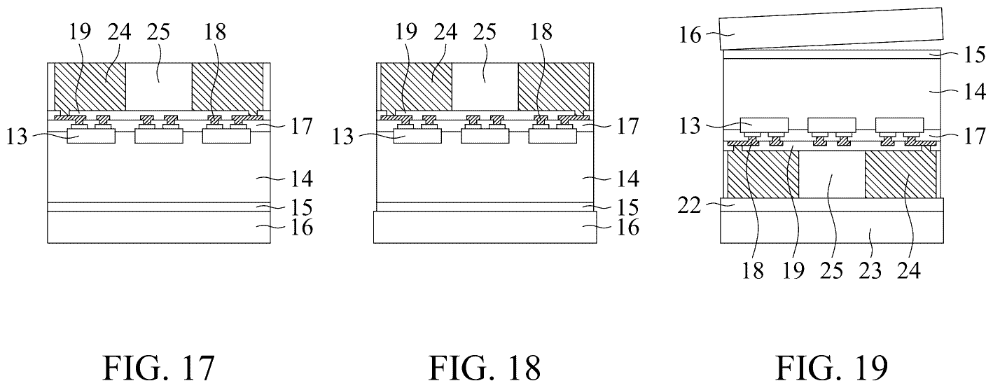

FIGS. 17 to 21 are schematic cross-sectional views showing the micro light-emitting diode package structure at various stages in the forming method according to other embodiments of the present disclosure. It should be noted that FIG. 17 is the subsequent step following FIG. 9. All previous steps may be referred to FIGS. 1 to 9, so the descriptions are omitted. In addition, steps similar to the foregoing steps are omitted. The main difference between this embodiment and the previous embodiment is that the conductive element 24 in this embodiment is a metal pillar instead of the solder pad in the previous embodiment. It should be noted that the use of metal pillar conductive elements 24 may greatly increase the thickness and volume of the metal layer, which is beneficial to current distribution, heat dissipation of LEDs, stress relief, pressure buffering during subsequent die bonding, and improvement of component life. It is of great help. In some embodiments, the metal pillar conductive element 24 is formed by electroplating, evaporation, screen printing, vacuum spraying, etc., and its thickness may be several times to dozens of times that of the solder pad conductive element 20 in another embodiment. In some embodiments, the thickness of the metal pillar conductive element 24 ranges from 5 μm to 100 μm.

Continuing from FIG. 9, as shown in FIG. 17, in some embodiments, the conductive elements 24 are disposed on the second insulating layer 19 and the redistribution layer 18, wherein the conductive elements 24 are electrically connected to the redistribution layer 18. In some embodiments, the conductive element 24 may be a metal pillar, but the present disclosure is not limited thereto. In some embodiments, the material of the conductive element 24 may be similar to or the same as the material of the redistribution layer 18, but the present disclosure is not limited thereto.

In some embodiments, a filler layer 25 is further disposed on the second insulating layer 19, wherein the filler layer 25 surrounds the conductive element 24. In some embodiments, the filler layer 25 may be or may include polyimide (PI), epoxy, other suitable materials, or a combination thereof, but the present disclosure is not limited thereto.

In some embodiments, the light transmittance (e.g., the light transmittance of the visible light range) of the filler layer 25 may be less than or equal to 70%. For example, the light transmittance of the filler layer 25 may be 70%, 65%, 60%, 55%, 50%, 45%, 40%, 35%, 30%, 25%, 20%, or any range of the above values. In some embodiments, the filler layer 25 may be or include a material with a light absorption rate greater than 90% so as to adjust the light transmittance of the filler layer 25. For example, black dispersed particles such as carbon black may be added to the filler layer 25 so that the light transmittance of the filler layer 25 is less than 10%. Therefore, the filler layer 25 appears black. By making the filler layer 25 appear black, elements located under the filler layer 25 (e.g., the redistribution layer 18) may be optically shielded. Optical devices such as photography devices may more easily perform alignment between the conductive element 24 and other electronic elements during the subsequent bonding process.

In some embodiments, the filler layer 25 is or includes a material with a high light absorption rate. In some embodiments, the light absorption rate of the filler layer 25 is greater than the light absorption rate of the second insulating layer 19.

As shown in FIG. 18, in some embodiments, similar to the description above, the filler layer 25 and the second insulating layer 19, the first insulating layer 17, the light-transmitting layer 14, and the second debond layer 15 disposed below the filler layer 25 which are between one group (e.g., the three shown in FIG. 18) of micro light-emitting diode dies 13 and another group (not shown) of micro light-emitting diode dies 13 are cut. For example, plasma dicing may be used to perform the above steps, but the present disclosure is not limited thereto. In other embodiments, the cutting process between the two groups of micro light-emitting diode dies 13 may also be performed by using lasers, knives, other suitable methods or tools, or a combination thereof.

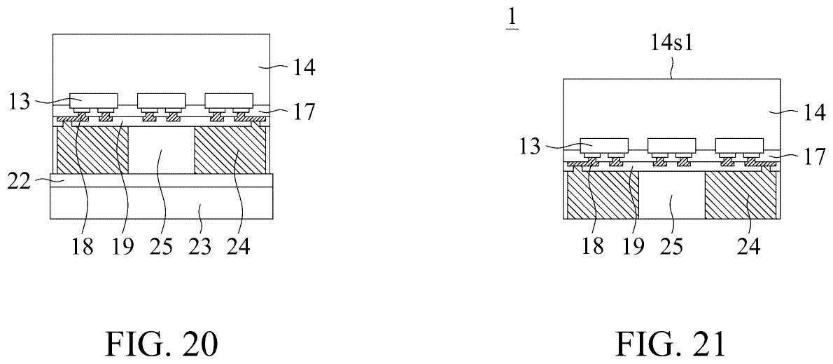

As shown in FIGS. 19 and 20, in some embodiments, a third substrate 23 is first bonded to the conductive element 24, then the second substrate 16 is turned over. For example, the third debond layer 22 may be disposed on the third substrate 23 first, and then the third substrate 23 may be bonded to the conductive element 24 through the third debond layer 22. Alternatively, the third debond layer 22 may also be disposed on the conductive element 24 first, and then the third substrate 23 is bonded to the third debond layer 22. Following the above process, the second substrate 16 is removed.

As shown in FIG. 21, in some embodiments, the third substrate 23 is removed. For example, the third debond layer 22 may lose its adhesion by heating, UV light, laser, etc. according to the type of the third debond layer 22, so as to remove the third substrate 23 thereon. Then, the third debond layer 22 may be removed by physical means or chemical means. It should be noted that the third debond layer 22 and the third substrate 23 may also be removed simultaneously in the same step using a suitable process, and the present disclosure is not limited to the above method.

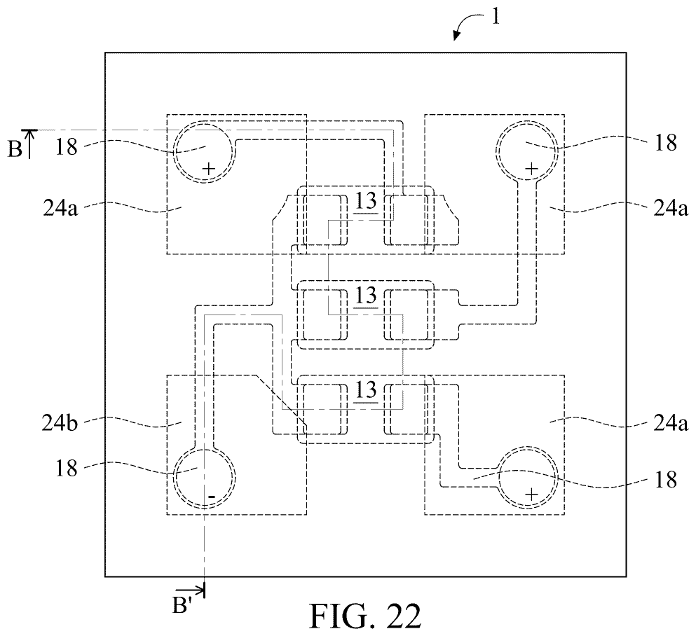

In addition to the advantages of the above-mentioned embodiment, this embodiment has a larger volume of the conductive element 24, thereby enabling better electrical connection with other elements. This is shown in FIG. 22, which is a top view showing the micro light-emitting diode package structure according to some embodiments of the present disclosure, and FIG. 22 is a cross-sectional view of line BB′ in FIG. 21. In some embodiments, the shapes of conductive elements 24 may be the same in the top view. In some embodiments, the shapes of conductive elements 24 may be different in the top view. In some embodiments, the common conductive element 24 is square in shape and has a triangular missing corner, and the other non-common conductive elements 24 are square in shape. In some embodiments, the triangular missing corner of the common conductive element 24 may be located at the upper left corner, upper right corner, lower left corner, or lower right corner of the square. In some embodiments, the shape of the common conductive element 24 is a square with two triangular missing corners. It should be noted that the present disclosure is not limited to the specific shape, size, material of the conductive element, etc. A person of ordinary skills in the art may select a suitable conductive element according to the requirements, in order to replace the above-mentioned conductive element 20, conductive element 24, and/or conductive element 37.

In the above, according to some embodiments of the present disclosure, the micro light-emitting diode package structure with a specific redistribution structure and forming method thereof have been generally described. The above-mentioned micro light-emitting diode package structure is manufactured using a redistribution last (RDL last) method. In the following, according to other embodiments of the present disclosure, some possible variations of the micro light-emitting diode package structure will be described, and micro light-emitting diode package structures manufactured using another RDL last method will be described. Specifically, the main difference between the following embodiments and the previous embodiments is that the micro light-emitting diode package structure in the following embodiments further includes additional elements or features, or may use different formation sequences to form various elements or features.

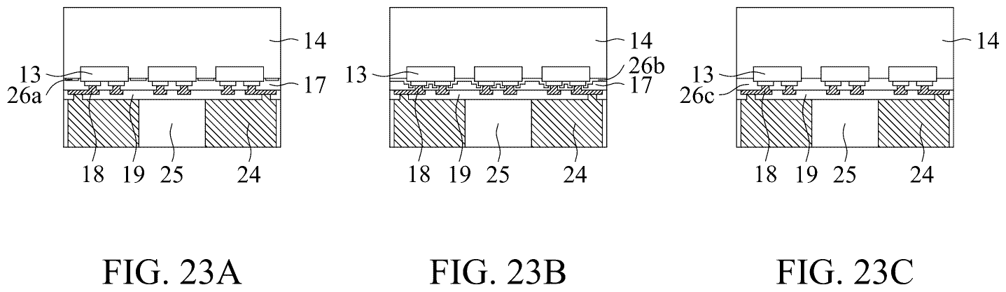

FIGS. 23A to 23C, which are schematic cross-sectional views showing a micro light-emitting diode package structure according to further embodiments of the present disclosure. In some embodiments, the micro light-emitting diode package structure may further include a reflective structure (e.g., reflective structures 26a to 26c hereinafter), and the reflective structure is disposed around the micro light-emitting diode die 13.

As shown in FIG. 23A, the reflective structure 26a may be disposed around or surround the micro light-emitting diode die 13. In some embodiments, the bottom surface of the reflective structure 26a may be coplanar with the electrode surface 13B of the micro light-emitting diode die 13, but the present disclosure is not limited thereto. Alternatively, as shown in FIG. 23B, the reflective structure 26b may be disposed conformally on the lower surface (e.g., the electrode surface 13B) of the micro light-emitting diode die 13 and disposed between the two micro light-emitting diode dies 13, and expose the electrode 130 of the micro light-emitting diode dies 13. In this case, the reflective structure 26b may have a larger coverage area than that of the reflective structure 26a so as to have a better light reflection effect.

In some embodiments, the reflective structure 26a or reflective structure 26b may include reflective material. For example, the reflective material may include silver (Ag), aluminum (Al), copper (Cu), chromium (Cr), titanium (Ti), the like, or a combination thereof, but the present disclosure is not limited thereto. Alternatively, the reflective material may be or include white paint, other white materials, the like, or a combination thereof, but the present disclosure is not limited thereto. In some embodiments, before the formation of the first insulating layer 17 (e.g., in the formation step of FIG. 6), the reflective structure 26a or the reflective structure 26b is formed on the micro light-emitting diode die 13 by electroplating, chemical vapor deposition, sputtering, resistance heating evaporation, electron beam evaporation, other suitable forming processes, or a combination thereof. In some embodiments, the reflective structure 26a or the reflective structure 26b includes multiple film layers with different refractive indexes to form a distributed Bragg reflector.

Alternatively, as shown in FIG. 23C, the reflective structure 26c may also be disposed to replace the first insulating layer 17. In this case, the micro light-emitting diode package structure does not have the first insulating layer, and the reflective structure 26c is used for electrical isolation and reflection of light at the same time. In some embodiments, the reflective material may be directly disposed to replace the first insulating layer 17. For example, in the formation step of FIG. 7, no dielectric material is disposed so that the first insulating layer 17 is not formed, and the reflective material is disposed to form the reflective structure 26c. In this case, the reflective structure 26c may include multiple film layers with different refractive indexes to form a distributed Bragg reflector.

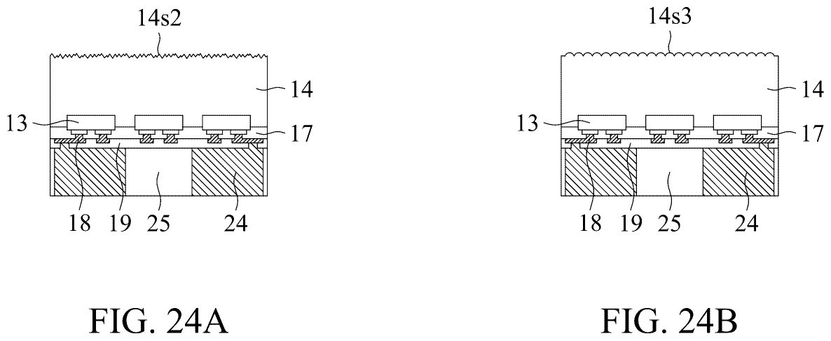

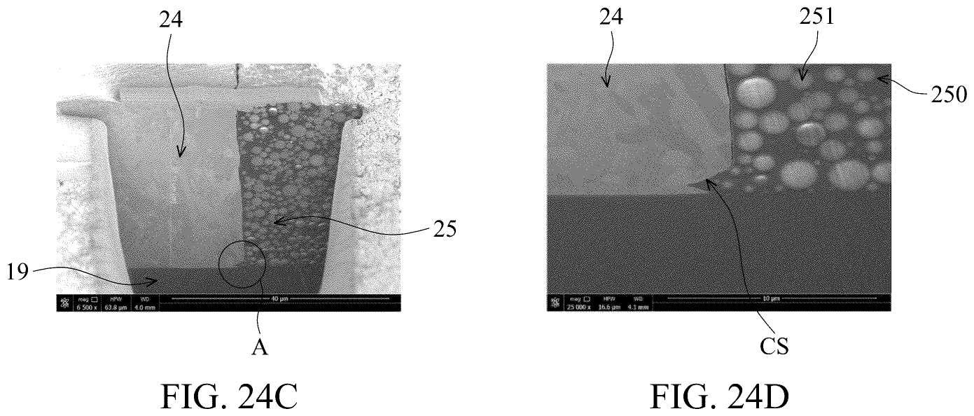

As shown in FIGS. 24A to 24B, which are schematic cross-sectional views showing a micro light-emitting diode package structure according to further embodiments of the present disclosure. In some embodiments, the light-transmitting layer 14 of the micro light-emitting diode package structure may have a roughened structure to improve the display effect. For example, the light of the micro light-emitting diode dies 13 may be converged or diverged through an uneven surface or a surface with a specific curvature. As shown in FIG. 24A, the light-transmitting layer 14 may have an irregular roughened surface 14s2. In this case, the light emitted by the micro light-emitting diode dies 13 will be scattered by the roughened surface 14s2 so that the light may be diverged evenly.

As shown in FIG. 24B, the light-transmitting layer 14 may also have a regular roughened surface 14s3. For example, the light-transmitting layer 14 may include a plurality of lens units protruding from the roughened surface 14s3 of the light-transmitting layer 14 in an array. However, the present disclosure is not limited thereto. In other embodiments, the number of lens units of the light-transmitting layer 14 may correspond to the number of micro light-emitting diode dies 13. For example, when the number of micro light-emitting diode dies 13 is three, the number of lens units may also be three. In this case, each of the lens units corresponds to one micro light-emitting diode die 13 and is disposed on that micro light-emitting diode die 13 to achieve the effect of controlling light.

In some embodiments, an optical layer (not shown) may also be disposed on the light-transmitting layer 14 to improve the light transmittance of the light emitted by the micro light-emitting diode die 13 to the light-transmitting layer 14. Referring to FIGS. 24C to 24D, FIGS. 24C to 24D are schematic cross-sectional views showing a micro light-emitting diode package structure according to further embodiments of the present disclosure. FIG. 24D is an enlarged schematic diagram showing area A in FIG. 24C. As shown in the drawings, in the present disclosure, the conductive element 24 has a concave structure CS adjacent to the second insulating layer 19, and the filler layer 25 surrounds the conductive element 24 and is filled into the concave structure CS of the conductive element 24. In some embodiments, the concave structures CS are located at both ends of the conductive element 24, and the filler layer 25 is filled into the concave structures CS located at both ends of the conductive element 24. In some embodiments, the concave structure CS may be annularly disposed on the periphery of the conductive element 24, and the filler layer 25 is filled into the concave structure CS located on the periphery of the conductive element 24. In some embodiments, the concave structure CS includes a tip gradually formed from the edge of the conductive element 24 to the inside of the conductive element 24. In some embodiments, in the schematic cross-sectional view, the concave structure CS is conical shape. In some embodiments, the filler layer 25 includes fillers 250 (e.g., the black portion in FIG. 24D) and diffusion particles 251 (Filler) (e.g., the white portion in FIG. 24D). In some embodiments, the diffusion particles include titanium dioxide (TiO₂), silicon dioxide (SiO₂), boron oxide (BN), aluminum oxide (Al₂O₃), or zirconium dioxide (ZrO₂). In some embodiments, the diffusion particles include hollow silicon dioxide (SiO₂) or solid silicon dioxide (SiO₂). In some embodiments, the filler layer 25 includes two or more different sizes of diffusion particles. For example, the filler layer 25 includes diffusion particles of two different sizes, three different sizes, four different sizes, or five or more different sizes. In some embodiments, the diffusion particles may be spherical or elongated. In some embodiments, the filler layer 25 includes two or more spherical diffusion particles with different radii. In some embodiments, the area of the concave structure CS filled by the filler layer 25 may only include the fillers 250. In some embodiments, the area of the concave structure CS filled by the filler layer 25 may include the filler 250 and the diffusion particles 251 (Filler).

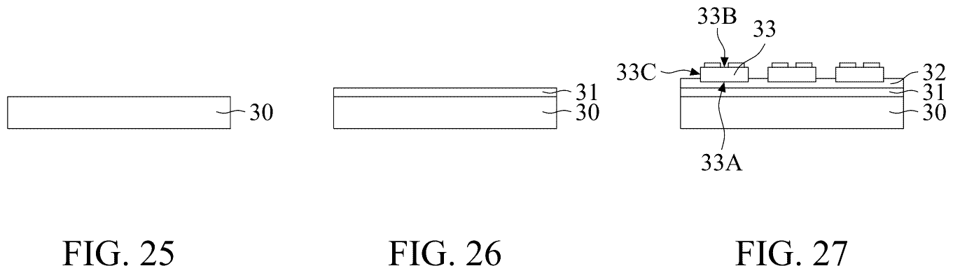

In some embodiments, the concave structure CS may be a structural feature produced by the interface between the seed layer used to form the conductive element 24 and the conductive element 24 itself, but the present disclosure is not limited thereto. By this structural feature, the adhesion between the conductive element 24 and the filler layer 25 may be improved (e.g., the contact area may be improved). Since the filler layer 25 is filled into the concave structure CS located in the conductive element 24, the reliability of the micro light-emitting diode package structure may increase. Referring to FIGS. 25 to 38, FIGS. 25 to 38 are schematic cross-sectional views showing micro light-emitting diode package structures at various stages in the forming method according to further embodiments of the present disclosure. It should be noted that the materials or functions of the elements or components mentioned in FIGS. 25 to 38 may be similar to or the same as the materials or functions of the elements or components mentioned in FIGS. 1 to 22, thereby omitting the repetition. For example, the first substrate 30 may be similar to or the same as the first substrate 10; the first insulating layer 34 may be similar to or the same as the first insulating layer 17; and the filler layer 38 may be similar to or the same as the filler layer 25. In addition, steps similar to the foregoing steps will be omitted. The main difference between this embodiment and the previous embodiments is that the steps of the method of this embodiment are different from those in the previous embodiments.

As shown in FIG. 25, a first substrate 30 is provided. As shown in FIG. 26, in some embodiments, a first debond layer 31 is disposed on the first substrate 30. As shown in FIG. 26, an adhesive layer 32 is disposed on the first debond layer 31, and a plurality of micro light-emitting diode dies 33 are disposed side by side on the adhesive layer 32. As shown in FIG. 27, in these embodiments, the light-emitting surface 33A of the micro light-emitting diode die 33 faces the first substrate 30, while the electrode surface 33B faces away from the first substrate 30. In other words, the light-emitting surface 33A of the micro light-emitting diode die 33 faces the adhesive layer 32 and contacts the adhesive layer 32.

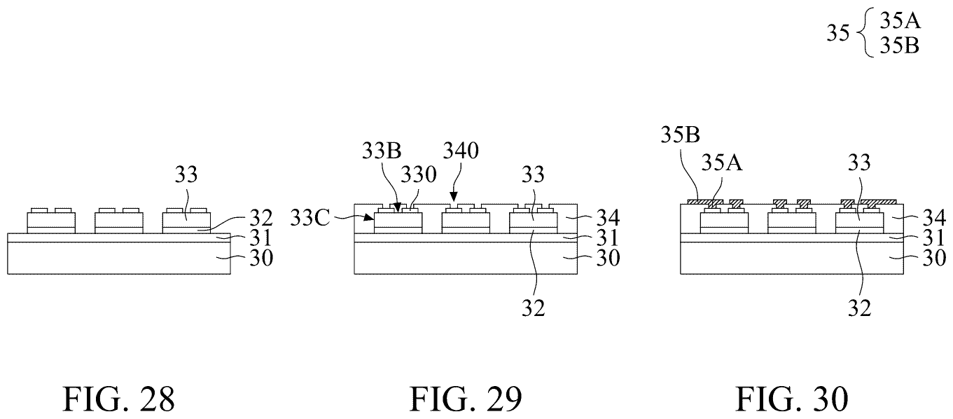

As shown in FIG. 28, a portion of the adhesive layer 32 is removed. Specifically, the portion of the adhesive layer 32 which is not covered by the micro light-emitting diode dies 33 may be removed through a removal process such as etching.

As shown in FIG. 29, a first insulating layer 34 is disposed on the electrode surface 33B of the micro light-emitting diode die 33, wherein the first insulating layer 34 is in direct contact with the electrode surface 33B and side surface 33C of the micro light-emitting diode die 33, and exposes the electrode 330 of the micro light-emitting diode dies 33. In some embodiments, the first insulating layer 34 continuously surrounds the side surface 33C of the micro light-emitting diode die 33. In some embodiments, the thicknesses of the micro light-emitting diode dies 33 are different; for example, red micro light-emitting diode die, blue micro light-emitting diode die, and green micro light-emitting diode die have different thicknesses. A first insulating layer 34 is formed on the micro light-emitting diode die 33, and the depths of the holes 340 exposing the electrodes 330 of the micro light-emitting diode dies 33 are different. In some embodiments, any two of the red LED, blue LED, and green LED in the micro light-emitting diode dies 33 may have different thicknesses. For example, the blue LED and green LED may have the same thickness, but the blue LED and red LED may have different thicknesses, and the green LED and red LED may have different thicknesses. The light-emitting surfaces 33A of these micro light-emitting diode dies 33 with different thicknesses may be made flush with each other through the redistribution layer provided later so as to maintain excellent display effects. In some embodiments, the thickness of the blue LED and the green LED is greater than that of the red LED.

As shown in FIG. 30, a plurality of redistribution layers 35 are disposed on the first insulating layer 34, wherein the redistribution layers 35 pass through the first insulating layer 34 and are respectively electrically connected to the electrodes 330 on the electrode surfaces 33B of the micro light-emitting diode dies 33. Similar to the description above, the extending lengths (also referred as thicknesses) of the vertical connection portions 35A of the redistribution layer 35 are different. In this way, the light-emitting surface 33A of each micro light-emitting diode die 33 may be substantially coplanar, and the horizontal connection portions 35B of the redistribution layer 35 corresponding to each micro light-emitting diode die 33 may be substantially coplanar.

In some embodiments, the thicknesses of the micro light-emitting diode dies 33 are the same; for example, the thicknesses of the red LED, the blue LED, and the LED dies are the same.

In some embodiments, when the thicknesses of the micro light-emitting diode dies 33 are the same, the first insulating layer 34 is formed on the micro light-emitting diode dies 33 and the depths of the holes 340 exposing the electrodes 330 of the micro light-emitting diode dies 33 are the same. A plurality of redistribution layers 35 are disposed on the first insulating layer 34, wherein the redistribution layers 35 pass through the first insulating layer 34 and are respectively electrically connected to the electrodes 330 on the electrode surfaces 33B of the micro light-emitting diode dies 33. The extension lengths (also referred as thicknesses) of the vertical connection portions 35A of the redistribution layer 35 are the same. In this way, the light-emitting surface 33A of each micro light-emitting diode die 33 may be substantially coplanar, and the horizontal connection portions 35B of the redistribution layer 35 corresponding to each micro light-emitting diode die 33 may be substantially coplanar.

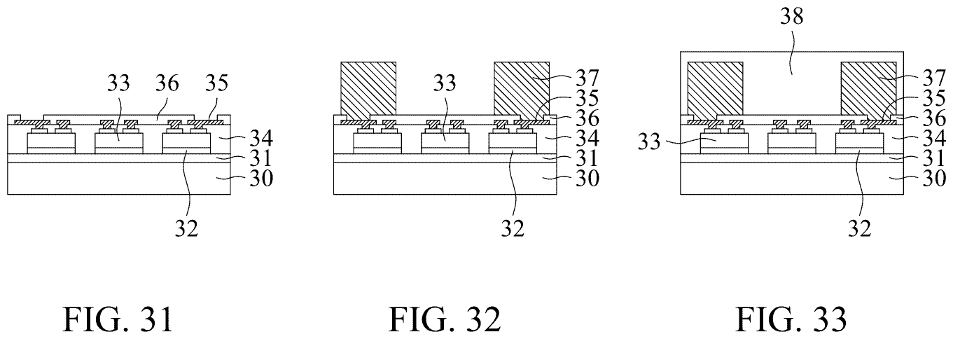

As shown in FIG. 31, a second insulating layer 36 is disposed on the first insulating layer 34, wherein the second insulating layer 36 covers the redistribution layer 35. In other words, the redistribution layer 35 is buried in the second insulating layer 36.

As shown in FIG. 32, a plurality of conductive elements 37 are disposed on the first insulating layer 34 and the redistribution layer 35, wherein the conductive element 37 is electrically connected to the redistribution layer 35. In some embodiments, the conductive element 37 may be a metal pillar, but the present disclosure is not limited thereto.

As shown in FIG. 33, a filler layer 38 is disposed on the second insulating layer 36, wherein the filler layer 38 surrounds and completely covers the conductive element 37.

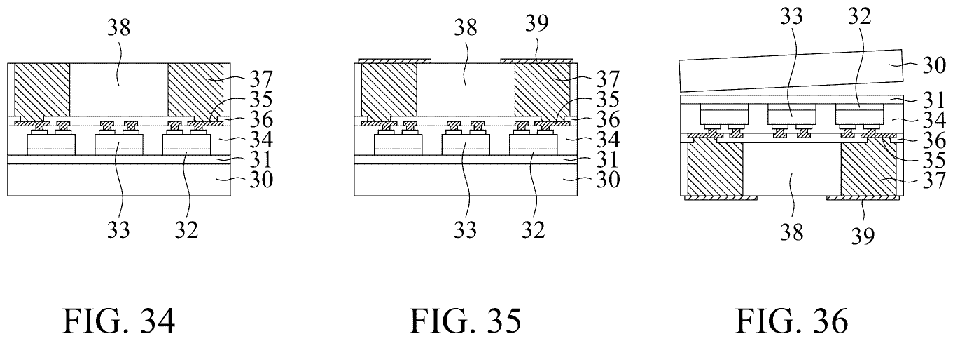

As shown in FIG. 34, a portion of the filler layer 38 is removed to expose the upper surface of the conductive element 37. For example, the filler layer 38 may be removed by methods such as chemical mechanical polishing, etching, other suitable methods, or a combination thereof, but the present disclosure is not limited thereto. In some embodiments, after exposing the upper surface of conductive element 37, the upper surface of filler layer 38 is coplanar with the conductive element 37.

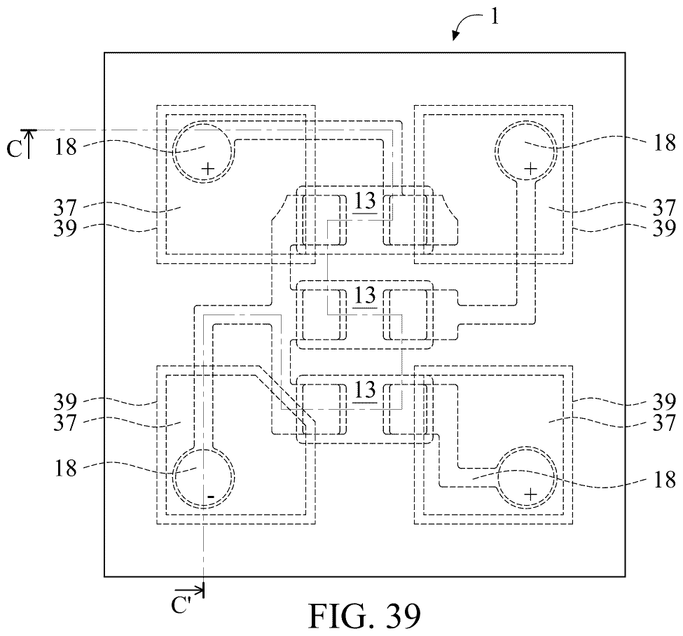

As shown in FIG. 35, a conductive pad 39 is disposed on the conductive element 37, and the upper surface of the conductive pad 39 and the upper surface of the filler layer 38 are not coplanar. The conductive pad 39 is electrically connected to the conductive element 37. In some embodiments, the conductive pad 39 covers the conductive element 37 and a portion of the filler layer 38 in the vertical direction. In other words, in the top view direction, the conductive pad 39 overlaps and is in directly contact with the conductive element 37, and the end or edge of the conductive pad 39 overlaps and is in directly contact with a portion of the filler layer 38. In some embodiments, the top view area of the conductive pad 39 may be greater than the top view area of the conductive element 37. In this way, in the top view direction, the conductive pad 39 may completely overlap and be in directly contact with the conductive element 37, and both ends or the entire edge of the conductive pad 39 may overlap and be in directly contact with a portion of the filler layer 38. Referring to FIG. 39, FIG. 39 is a top view showing a micro light-emitting diode package structure according to some embodiments of the present disclosure, and FIG. 39 is a cross-sectional view of line C-C′ in FIG. 38. In some embodiments, the number of conductive pads 39 may be four, one of which is a common conductive pad 39. In some embodiments, the shapes of conductive pads 39 may be the same in the top view. In some embodiments, the shapes of the conductive pads 39 may be different in the top view. In some embodiments, the common conductive pad 39 is square in shape and has a triangular missing corner, and the other non-common conductive pads 39 are square in shape. In some embodiments, the triangular missing corner of the common conductive pad 39 may be located at the upper left corner, upper right corner, lower left corner, or lower right corner of the square. In some embodiments, the shape of the common conductive pad 39 is a square with two triangular missing corners.

In some embodiments, the conductive pad 39 overlaps the redistribution layer 35 in the top view. In some embodiments, some micro light-emitting diode dies 33 overlap two conductive pads 39 in the top view direction. For example, the configuration may be similar to that shown in FIG. 16, but the present disclosure is not limited thereto. It should be noted that although the embodiments of FIGS. 1 to 22 do not specifically show conductive pads, the conductive pads of this embodiment may also be applied to the aforementioned embodiments.

In some embodiments, the conductive pad 39 may be or include conductive material. The conductive material may include metal, metal compounds, other suitable conductive materials, or a combination thereof, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or their alloys. For example, the metal compound may be tantalum nitride (TaN), titanium nitride (TiN), tungsten silicide (WSi₂), indium tin oxide (ITO), etc.

As shown in FIG. 36, the first substrate 30 is turned over and removed. For example, the first debond layer 31 may lose its adhesion by heating, UV light, laser, etc. according to the type of the first debond layer 31, so as to remove the first substrate 30 thereon.

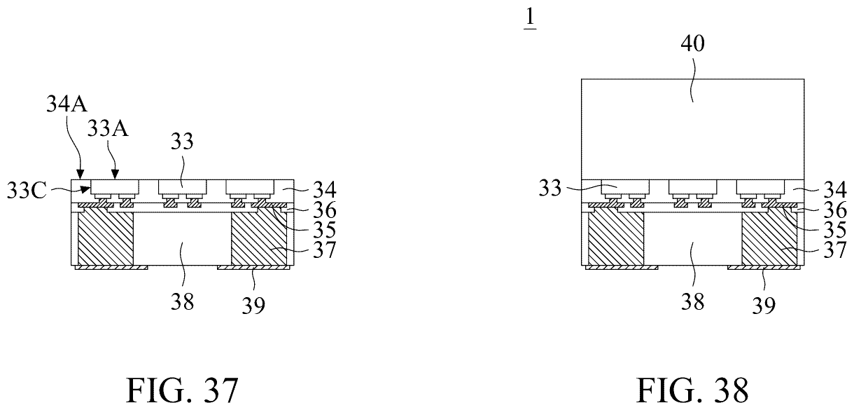

As shown in FIG. 37, the adhesive layer 32 and a portion of the first insulating layer 34 are removed to expose the light-emitting surface 33A of the micro light-emitting diode die 33. For example, the adhesive layer 32 and the portion of the first insulating layer 34 may be removed through a removal process such as etching, polishing, other suitable methods, or a combination thereof. After the removal of the adhesive layer 32 and the portion of the first insulating layer 34, the upper surface 34A of the first insulating layer 34 may be coplanar with the light-emitting surface 33A, but the present disclosure is not limited thereto. In some embodiments, the removal process used for removing the adhesive layer 32 and the portion of the first insulating layer 34 may be performed until the upper surface 34A of the first insulating layer 34 is lower than the light-emitting surface 33A in order to ensure that the adhesive layer 32 on the light-emitting surface 33A is completely removed. In this case, the upper surface 34A of the first insulating layer 34 may be in contact with the side surface 33C of the micro light-emitting diode die 33. In some embodiments, the first insulating layer 34 continuously surrounds the side surfaces 33C of the micro light-emitting diode die 33. The first insulating layer 34 is filled between the electrodes 330 of the micro light-emitting diode dies 33. Therefore, before the aforementioned removal process of the adhesive layer 32 and the portion of the first insulating layer 34, the first insulating layer 34 may prevent the micro light-emitting diode die 33 from falling off. Moreover, after the removal process of the adhesive layer 32 and the portion of the first insulating layer 34, the first insulating layer 34 fixes the micro light-emitting diode die 33 in the micro light-emitting diode package structure 1. As shown in FIG. 38, a light-transmitting layer 40 is disposed to cover the light-emitting surface 33A of the micro light-emitting diode die 33 in order to form a micro light-emitting diode package structure 1. In some embodiments, when the upper surface 34A of the first insulating layer 34 is lower than the light-emitting surface 33A, the light-transmitting layer 40 may cover the light-emitting surface 33A and the side surfaces 33C of the micro light-emitting diode die 33. In some embodiments, the side surfaces of the light-transmitting layer 40, the side surfaces of the first insulating layer 34, the second insulating layer 36, and the filler layer 38 are coplanar. In some embodiments, the micro light-emitting diode package structure 1 is a cube or a cuboid.

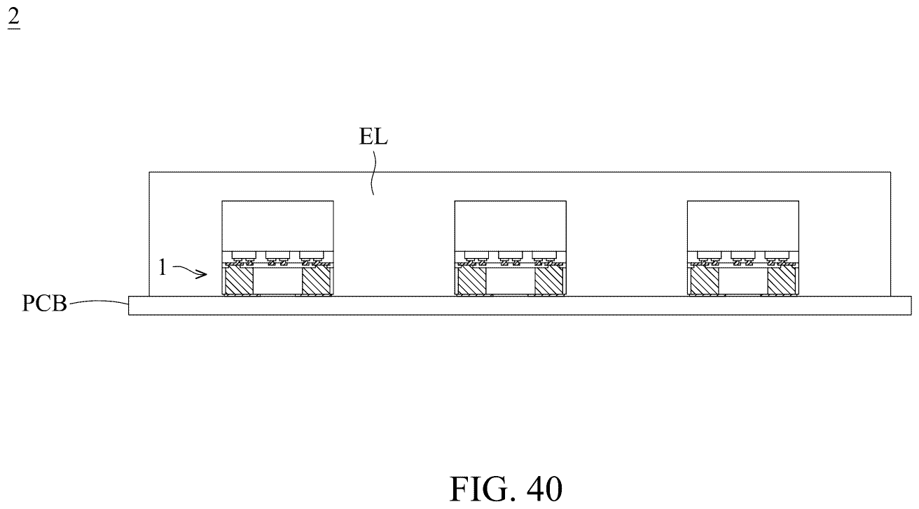

Referring to FIG. 40, FIG. 40 is a schematic diagram showing a display module according to some embodiments of the present disclosure. The micro light-emitting diode package structure 1 may be used as a pixel unit in a display device. In some embodiments, the micro light-emitting diode package structure 1 of the present disclosure may be applied in a display module 2 and used as a pixel unit. As shown in FIG. 38, the display module 2 includes a micro light-emitting diode package structure 40 and a printed circuit board PCB. The micro light-emitting diode package structure 1 may be electrically connected to the printed circuit board PCB. In some embodiments, the micro light-emitting diode package structure 1 and the printed circuit board PCB are electrically connected through a bonding material. In some embodiments, the micro light-emitting diode package structure 1 is encapsulated by using an encapsulating material EL to form one display module 2. In some embodiments, the material of the encapsulating material EL may be similar to or the same as the material of the light-transmitting layers 14 and 40, but the present disclosure is not limited thereto. In some embodiments, the material of the encapsulating material is different from the material of the light-transmitting layers 14 and 40, but the present disclosure is not limited thereto. In some embodiments, the encapsulating material EL is a transparent material, but the present disclosure is not limited thereto.

It should be noted that although FIG. 40 shows a possible structure and configuration of the display module 2, the present disclosure is not limited thereto. In other embodiments, the micro light-emitting diode package structure 1 of the present disclosure may also be applied to various display modules that are well known to a person of ordinary skills in the art. In some embodiments, the display module 2 of the present disclosure may be spliced into display devices with various sizes.

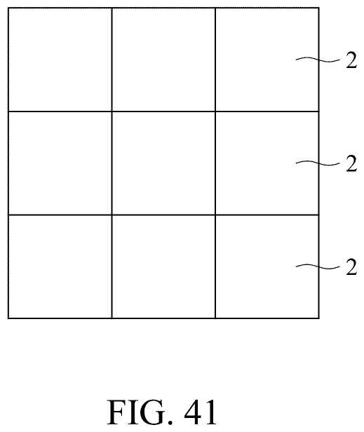

Referring to FIG. 41, FIG. 41 is a schematic diagram showing a spliced display device according to some embodiments of the present disclosure. In some embodiments, the micro light-emitting diode package structure 1 of the present disclosure may be applied to a display module 2, and multiple display modules 2 may be applied to multiple display devices. As shown in the drawings, the multiple display devices including multiple display modules 2 may be jointly applied as the spliced display device.

The components in the embodiments of the present disclosure may be used together and combined as long as they do not violate the spirit of the disclosure or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the aforementioned process, machine, manufacturing, material composition, device, method, and steps. It is not necessary for any embodiment or claim of the present disclosure to achieve all of the objects, advantages, and/or features disclosed herein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A micro light-emitting diode package structure, comprising:
a plurality of micro light-emitting diode dies disposed side by side, wherein the plurality of micro light-emitting diode dies each includes an electrode surface, a light-emitting surface, and a plurality of side surfaces, the electrode surface and the light-emitting surface are opposite to each other, and the plurality of side surfaces are between the electrode surface and the light-emitting surface;
a light-transmitting layer covering the light-emitting surface and the plurality of side surfaces of the plurality of micro light-emitting diode dies;
a first insulating layer disposed under the plurality of micro light-emitting diode dies, wherein the electrode surface of the plurality of micro light-emitting diode dies is in direct contact with the first insulating layer;
a plurality of redistribution layers disposed under the first insulating layer and passing through the first insulating layer to electrically connect to the electrode surface of the plurality of micro light-emitting diode dies; and
a plurality of conductive elements disposed under the plurality of redistribution layers and electrically connected to the plurality of redistribution layers.

2. The micro light-emitting diode package structure as claimed in claim 1, wherein the first insulating layer comprises epoxy, polyimide (PI), polybenzoxazole (PBO), silicone, silicon dioxide, silicon nitride, or a combination thereof.

3. The micro light-emitting diode package structure as claimed in claim 1, wherein the light-transmitting layer comprises epoxy, silicone, polyurethane, or a combination thereof.

4. The micro light-emitting diode package structure as claimed in claim 1, wherein a light transmittance of the light-transmitting layer is greater than a light transmittance of the first insulating layer.

5. The micro light-emitting diode package structure as claimed in claim 1, wherein a first contact surface is between the first insulating layer and the light-transmitting layer, and a second contact surface is between the first insulating layer and the electrode surface of the plurality of micro light-emitting diode dies, wherein the first contact surface and the second contact surface are not coplanar.

6. The micro light-emitting diode package structure as claimed in claim 1, wherein the first insulating layer partially covers the plurality of side surfaces of the plurality of micro light-emitting diode dies.

7. The micro light-emitting diode package structure as claimed in claim 1, further comprising a second insulating layer disposed under the first insulating layer, wherein the plurality of redistribution layers are buried in the second insulating layer.

8. The micro light-emitting diode package structure as claimed in claim 7, wherein the plurality of conductive elements are solder pads, and the micro light-emitting diode package structure further comprises a hard mask layer, wherein the hard mask layer is disposed under the second insulating layer and surrounds the plurality of conductive elements.

9. The micro light-emitting diode package structure as claimed in claim 8, wherein the hard mask layer comprises silicon oxide.

10. The micro light-emitting diode package structure as claimed in claim 7, wherein the plurality of conductive elements are metal pillars, and the micro light-emitting diode package structure further comprises a filler layer, wherein the filler layer is disposed under the second insulating layer and surrounds the plurality of conductive elements.

11. A forming method of a micro light-emitting diode package structure, comprising:
disposing a plurality of micro light-emitting diode dies side by side on a first substrate, wherein the plurality of micro light-emitting diode dies each includes an electrode surface, a light-emitting surface, and a plurality of side surfaces, wherein the electrode surface and the light-emitting surface are opposite to each other, and the plurality of side surfaces are between the electrode surface and the light-emitting surface;
disposing a light-transmitting layer to cover the light-emitting surface and the plurality of side surfaces of the plurality of micro light-emitting diode dies;
removing the first substrate to expose the electrode surface of the plurality of micro light-emitting diode dies;
disposing a first insulating layer on the electrode surface of the plurality of micro light-emitting diode dies, wherein the first insulating layer is in direct contact with and covers the electrode surface of the plurality of micro light-emitting diode dies;
disposing a plurality of redistribution layers on the first insulating layer, wherein the plurality of redistribution layers pass through the first insulating layer and are electrically connected to the electrode surface of the plurality of micro light-emitting diode dies; and
disposing a plurality of conductive elements on the plurality of redistribution layers, wherein the plurality of conductive elements are electrically connected to the plurality of redistribution layers.

12. The forming method of the micro light-emitting diode package structure as claimed in claim 11, wherein removing the first substrate comprises removing an adhesive layer between the first substrate and the plurality of micro light-emitting diode dies to remove the first substrate and expose the electrode surface.

13. The forming method of the micro light-emitting diode package structure as claimed in claim 11, wherein before removing the first substrate, the forming method further comprises:
bonding a second substrate on the light-transmitting layer; and
turning over the first substrate after bonding the second substrate.

14. The forming method of the micro light-emitting diode package structure as claimed in claim 13, wherein after disposing the plurality of conductive elements on the plurality of redistribution layers, the forming method further comprises:
bonding a third substrate to the conductive elements;
turning over the second substrate after bonding the third substrate; and
removing the second substrate.

15. The forming method of the micro light-emitting diode package structure as claimed in claim 14, wherein after removing the second substrate, the forming method further comprises removing the third substrate.

16. The forming method of the micro light-emitting diode package structure as claimed in claim 11, wherein a first contact surface is between the first insulating layer and the light-transmitting layer, and a second contact surface is between the first insulating layer and the electrode surface of the plurality of micro light-emitting diodes, wherein the first contact surface and the second contact surface are not coplanar.

17. The forming method of the micro light-emitting diode package structure as claimed in claim 11, wherein disposing the first insulating layer further comprises partially covering the first insulating layer on the plurality of side surfaces of the plurality of micro light-emitting diode dies.

18. The forming method of the micro light-emitting diode package structure as claimed in claim 11, wherein before disposing the plurality of conductive elements on the plurality of redistribution layers, further comprising disposing a second insulating layer on the first redistribution layer, wherein the second insulating layer covers the plurality of redistribution layers.

19. The forming method of the micro light-emitting diode package structure as claimed in claim 18, wherein the plurality of conductive elements are solder pads, and after disposing the plurality of conductive elements on the plurality of redistribution layers, the forming method further comprises disposing a hard mask layer on the second insulating layer, wherein the hard mask layer surrounds the conductive elements.

20. The forming method of the micro light-emitting diode package structure as claimed in claim 18, wherein the plurality of conductive elements are metal pillars, and after disposing the plurality of conductive elements on the plurality of redistribution layers, the forming method further comprises disposing a filler layer on the second insulating layer, wherein the filler layer surrounds the conductive elements.
